(19) United States
(12) Patent Application Publication
(10) Pub. No.: US 2017/0334295 A1
(43) Pub. Date: Nov. 23, 2017

(54) TESTER FOR MEASURING ISOLATION BETWEEN A HIGH VOLTAGE DIRECT CURRENT SYSTEM AND A CHASSIS

(71) Applicants: Qian Turner, Clarkston, MI (US); Yuriy Taborisskiy, West Bloomfield, MI (US)

(72) Inventors: Qian Turner, Clarkston, MI (US); Yuriy Taborisskiy, West Bloomfield, MI (US)

(21) Appl. No.: 15/159,087

(22) Filed: May 19, 2016

(51) Int. Cl. B60L 3/00; G01R 31/00

(52) U.S. Cl. CPC B60L 3/0069; G01R 31/006

(57) ABSTRACT

A high voltage isolation tester has a high voltage side and a low voltage side coupled to each other by isolation amplifiers so that the high and low voltage sides are electrically isolated from each other. The high voltage side includes positive and negative high voltage test inputs and a common test input. The high voltage side also includes a positive switched voltage divider network and a negative switched voltage divider network. The low voltage side includes a controller that automatically controls switching of the switched voltage divider networks to make voltage measurements of voltages at inputs of the isolation amplifiers. Outputs of the isolation amplifiers are coupled to inputs of an analog-to-digital converter and the digitized voltages are read from the analog-to-digital converter by the controller.

The present invention relates to a tester for measuring isolation of a high voltage direct current system from a chassis on which the high voltage direct current system is mounted.

### BACKGROUND

Federal Motor Vehicle Safety Standard (“FMVSS”) 305 governs measuring the isolation of a DC high voltage system of an electric or hybrid electric vehicle and a chassis of the vehicle. Typically, people who make the voltage measurements in accordance with FMVSS 305 use a voltmeter with test probes that the person making the measurements applies to the appropriate test points of the vehicle such as to the positive high voltage rail, the negative high voltage rail and the chassis. Since this presents the possibility that the person making the measurements could come into contact with high voltage, those who make FMVSS 305 measurements need wear personal protection gear and be trained in making high voltage measurements including appropriate safety procedures. Also, once the voltage measurements are made, then the isolation must be determined from the voltage measurements which is typically done by the person making the voltage measurements.

### SUMMARY

In accordance with an aspect of the present disclosure, a high voltage isolation tester has a high voltage side and a low voltage side that are coupled to each other by isolation amplifiers. The high voltage side has a positive test input coupled by a positive side switched voltage divider network to an input of a first one of the isolation amplifiers. The positive side switched voltage divider network has first and second resistances that are different resistances. The high voltage side has a negative test input coupled by a negative side switched voltage divider network to an input of a second one of the isolation amplifiers. The negative side switched voltage divider network has third and fourth resistances that are different resistances. The high voltage side has a common test input. The positive test input and the negative test input are coupled to opposite sides of a voltage divider network of resistances with a junction of the resistances coupled to an input of a third one of the isolation amplifiers. The low side includes an analog-to-digital converter to which outputs of the isolation amplifiers are coupled. The low side includes a controller that controls switching of the positive and negative side switched voltage divider networks, reads from the analog-to-digital converter digitized data of voltage measurements of voltages across the high voltage test input and common test input, voltages across the negative high voltage test input and the common test input, and a voltage across the positive and negative high voltage test inputs. The controller is configured with control logic to switch the positive side switched voltage divider network to couple the positive high voltage test input to the input of the first isolation amplifier through the first resistance and then through the second resistance and take voltage measurements of the voltage at the input of the first isolation amplifier when the positive high voltage test input is coupled to the input of the first isolation amplifier through the first resistance and also when the positive high voltage test input is coupled to the input of the first isolation amplifier through the second resistance. The controller is also configured with control logic to switch the negative side switched voltage divider network to couple the negative high voltage test input to the input of the second isolation amplifier through the third resistance and then through the fourth resistance and take voltage measurements of the voltage at the input of the second isolation amplifier when the negative high voltage input is coupled to the input of the second isolation amplifier through the third resistance and also when the negative high voltage test input is coupled to the input of the second isolation amplifier through the fourth resistance. The controller is also configured with configured with control logic to take a voltage measurement of a voltage at the input of the third isolation amplifier.

In an aspect, the controller is configured with control logic to determine isolation between the positive high voltage test input and common test input and isolation between the negative high voltage test input and common test input based on the voltage measurements of the voltages at the inputs of the first and second isolation amplifiers.

In an aspect, the controller is configured with control logic to communicate each determined isolation to a desired destination.

In an aspect, the controller is configured with control logic to communicate the voltage measurements to a desired destination.

### BRIEF DESCRIPTION OF THE DRAWINGS

The present invention will become more fully understood from the detailed description and the accompanying drawings, wherein:

FIG. 1 is a simplified schematic of a high voltage isolation tester in accordance with an aspect of the present disclosure; and

FIG. 2 is a flow chart of control logic of a control routine implemented in a controller of the tester of FIG. 1 for controlling the tester of FIG. 1.

### DETAILED DESCRIPTION

Further areas of applicability of the teachings of the present disclosure will become apparent from the detailed description, claims and the drawings provided hereinafter, wherein like reference numerals refer to like features throughout the several views of the drawings. It should be understood that the detailed description, including disclosed embodiments and drawings referenced therein, are merely exemplary in nature intended for purposes of illustration only and are not intended to limit the scope of the present disclosure, its application or uses. Thus, variations that do not depart from the gist of the present disclosure are intended to be within the scope of the present disclosure.

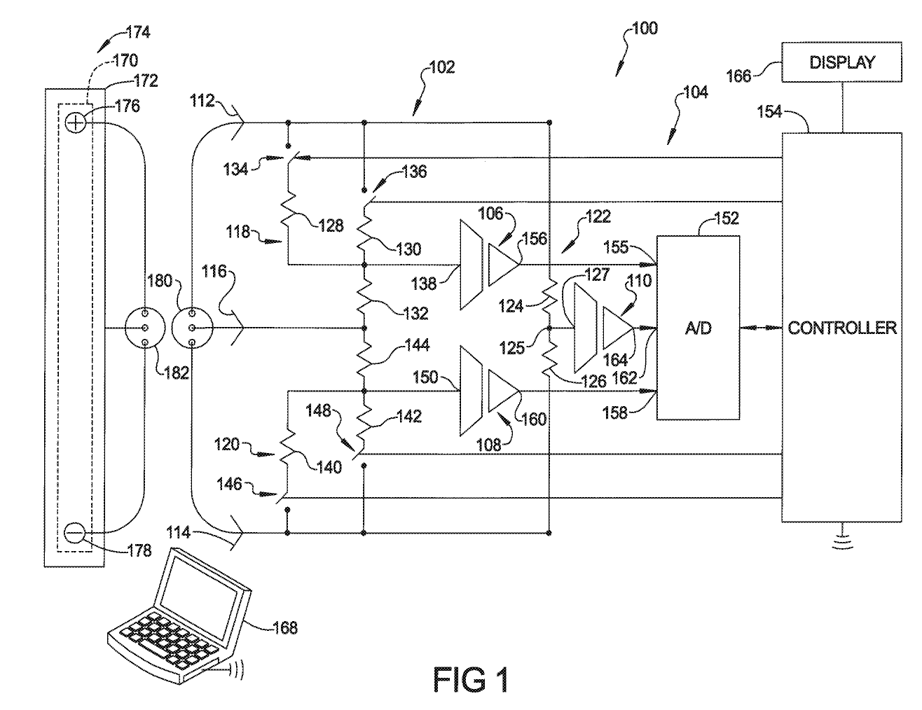

FIG. 1 is a simplified schematic of an automated high voltage isolation tester 100 in accordance with an aspect of the present disclosure. Tester 100 has a high voltage side 102 and a low voltage side 104 that are coupled to each other by a plurality of isolation amplifiers 106, 108, 110. As is known in the art, an isolation amplifier is a type of differential operational amplifier that has electrical isolation between its inputs and its output. In an example, isolation amplifiers 106, 108, 110 are isolation amplifiers available from TI Electronics such as an AMC1200-Q1, AMC1100, AMC1200, ISO124, ISO122, ISO121 or AMC1301 isolation amplifiers. High voltage side 102 and low voltage side 104 are thus electrically isolated from each other.

High voltage side 102 includes a positive high voltage test input 112, a negative high voltage test input 114 and a common test input 116. High voltage side 102 also includes a positive side switched voltage divider network 118 coupled across positive high voltage test input 112 and common test input 116 and a negative side switched voltage divider network 120 coupled across negative high voltage test input 114 and common test input 116. High voltage side 102 also includes a voltage divider network 122 coupled across positive test input 112 and negative test input 114. Voltage divider network 122 includes resistances 124, 126 coupled in series across positive test input 112 and negative test input 114 with a junction 125 of resistances 124, 126 coupled to an input 128 of isolation amplifier 110. Resistances 124, 126 illustratively have the same resistivity.

Positive side switched voltage divider network 118 includes resistances 128, 130, 132 and controlled switches 134, 136. In an example controlled switches 134, 136 are solid state relays and in another example, are mechanical relays. Resistances 128, 130 are referred to herein as higher and lower resistances 128, 130, respectively, and have different resistivities and which are also different than a resistivity of resistance 132. In this regard, the terms higher resistance 128 and lower resistance 130 are relative with respect to each other meaning that higher resistance 128 has a resistivity that is higher than a resistivity of lower resistance 130. Illustratively, higher resistance 128 has a resistivity that is 10 times the resistivity of lower resistance 130 and one-hundred times the resistivity of resistance 132. Illustratively, higher resistance 128 has a resistivity of 1 mega ohms, lower resistance 130 has a resistivity of 100 K ohms, and resistance 132 has a resistivity of 1 K ohms. Positive high voltage test input 112 is switched by controlled switch 134 through higher resistance 128 to an input 138 of isolation amplifier 106 and by controlled switch 136 through lower resistance 130 to input 138 of isolation amplifier 106. Resistance 132 is coupled across input 138 of isolation amplifier 106 and common test input 116.

Negative side switched voltage divider network 120 has the same circuit topology as positive side switched voltage divider network 118. Negative side switched voltage divider network includes resistances 140, 142, 144 and controlled switches 146, 148. In an example controlled switches 146, 148 are solid state relays and in another example, are mechanical relays. Resistances 140, 142 are referred to herein as higher and lower resistances 140, 142, respectively, and have different resistivities and which are also different than a resistivity of resistance 144. In this regard, the terms higher resistance 140 and lower resistance 142 are relative with respect to each other meaning that higher resistance 140 has a resistivity that is higher than a resistivity of lower resistance 142. Illustratively, higher resistance 140 has a resistivity that is 10 times the resistivity of lower resistance 142 and one-hundred times the resistivity of resistance 144. Illustratively, higher resistance 140 has a resistivity of 1 mega ohms, lower resistance 142 has a resistivity of 100 K ohms, and resistance 144 has a resistivity of 1 K ohms. Negative high voltage test input 114 is switched by controlled switch 146 through higher resistance 140 to an input 150 of isolation amplifier 108 and by controlled switch 148 through lower resistance 142 to input 150 of isolation amplifier 108. Resistance 142 is coupled across input 150 of isolation amplifier 108 and common test input 116.

Low side 104 has an analog-to-digital converter 152 in data communication with a controller 154. Analog-to-digital converter 152 has an input 155 to which an output 156 of isolation amplifier 106 is coupled, an input 158 to which an output 160 of isolation amplifier 108 is coupled, and an input 162 to which an output 164 of isolation amplifier 110 is coupled. It should be understood that inputs 155, 158 and 162 can be individual, separate inputs or multiplexed inputs. It should also be understood that analog-to-digital converter 152 and controller 154 can be separate devices or controller 154 can include analog-to-digital converter 152. Controller 154 illustratively communicates wirelessly, wired, or both, with a desired destination or destinations, such as a display 166 and/or a remote device such as a personal computer 168.

In an aspect, controller 154 is configured with control logic controlling tester 100 to measure isolation of a high voltage system 170 to a chassis 172 in a motor vehicle 174, such as an electric or hybrid electric motor vehicle, in accordance with Federal Motor Vehicle Safety Standard (“FMVSS”) 305. Positive high voltage test input 112 and negative high voltage test input 114 are connected to a positive high voltage rail 176 and a negative high voltage rail 178, respectively, of high voltage system 170 and common test input 116 is connected to chassis 172. Illustratively, positive high voltage test input 112, negative high voltage test input 114 and common test input 116 are disposed in a connector 180 shown representatively by dashed lines in FIG. 1 which mates with a corresponding connector of vehicle 174 to which positive high voltage rail 176, negative high voltage rail 178 and chassis 172 are connected.

In making measurements from which the isolation of high voltage system 170 to chassis 172 is determined in accordance with FMVSS 305, tester 100 automatically makes the following measurements: Va and Va′ which are both voltages indicative of the voltage across the high voltage test input 112 and the common test input 116, using the higher resistance 128 in the positive side switched voltage divider network 118 in measuring Va and lower resistance 130 in measuring Va′; Vb and Vb′ which are both voltages indicative of the voltage across the negative high voltage test input 114 and the common test input 116, using the higher resistance 140 in the negative side switched voltage divider network 120 in measuring Vb and lower resistance 130 in measuring Vb′; and Vc which is a voltage across high voltage test input 112 and negative high voltage test input 114. In an aspect, controller 154 then determines the isolation between high voltage system 170 and chassis 172 using the formulas set out in FMVSS 305, or tester 100 sends Va, Va′, Vb, Vb′, Vc to a desired destination, such as personal computer 168 which determines the isolation between the positive high voltage rail 176 and chassis 172 and the isolation between high voltage system 170 and chassis 172, or both. When controller 154 determines the isolation, controller 154 then sends the determined isolation to a desired destination, such as to personal computer X, display 166, or both.

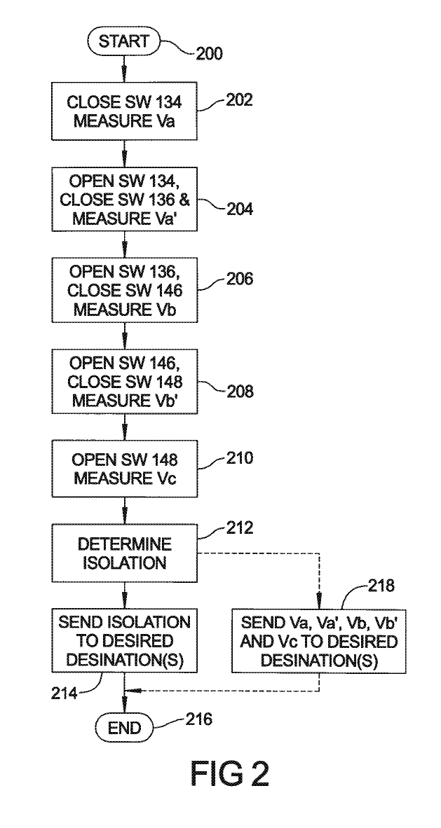

FIG. 2 is a flow chart of illustrative control logic for a control routine implemented in controller 154 for controlling tester 100 to measure the isolation between high voltage system 170 and chassis 172. The control routine starts at 200 and proceeds to 202. At 202, controller 154 closes controlled switch 134 coupling positive high voltage test input 112 to input 138 of isolation amplifier 106 through higher resistance 128 and measures Va. In this regard, the measured Va voltage is an analog voltage at the output of isolation amplifier 106 that is digitized by analog-to-digital converter 152 and the digitized value of Va communicated to controller 154 which stores it as the measured Va voltage. The control routine then proceeds to 204 where controller 154 opens controlled switch 134, closes controlled switch 136 coupling high voltage test input 112 to input 138 of operational amplifier 106 through lower resistance 130 and measures Va′. In this regard, the measured Va′ is also an analog voltage at the output of isolation amplifier 106 that is digitized by analog-to-digital converter 152 and the digitized value of V2 communicated to controller 154 which stores it as the measured Va′ voltage. It should be understood that Va and Va′ are both voltages indicative of a voltage across positive high voltage test input 112 and common test input 116 but Va′ will have a lower absolute value than Va since lower resistance 130 has a lower resistivity than higher resistance 128.

The control routine next proceeds to 206 where controller opens controlled switch 136, closes controlled switch 146 coupling negative high voltage test input to input 150 of operational amplifier 108 through higher resistance 140 and measures Vb. In this regard, the measured Vb voltage is an analog voltage at the output of isolation amplifier 108 that is digitized by analog-to-digital converter 152 and the digitized value of Vb communicated to controller 154 which stores it as the measured Vb voltage. The control routine then proceeds to 208 where controller 154 opens controlled switch 146, closes controlled switch 148 coupling negative high voltage test input 114 to input 150 of isolation amplifier 108 through lower resistance 142 and measures Vb′. In this regard, the measured Vb′ voltage is an analog voltage at the output of isolation amplifier 108 that is digitized by analog-to-digital converter 152 and the digitized value of Vb′ communicated to controller 154 which stores it as the measured Vb′ voltage. It should be understood that Vb and Vb′ are both voltages indicative of a voltage across negative high voltage test input 114 and common test input 116 but Vb′ will have a lower absolute value than Vb since lower resistance 142 has a lower resistivity than higher resistance 140.

The control routine next proceeds to 210 where controller 154 opens controlled switch 148, measures Vc, and opens controlled switch 148. In this regard, the measured Vc voltage is an analog voltage at output 164 of isolation amplifier 110 that is digitized by analog-to-digital converter 152 and the digitized value of Vc communicated to controller 154 that stores it as the measured Vc voltage. As can be seen, the voltage at input 127 of isolation amplifier 110 is an analog voltage at the junction of resistances 124, 126 of voltage divider network 122 and indicative of a voltage across positive high voltage test input 112 and negative high voltage test input 114.

The control routine then proceeds to 212 where controller 154 determines the isolation between high voltage system 170 and chassis 172 in accordance with FMVSS 305. If Vb is greater than or equal to Va, then controller 154 determines the isolation between high voltage system 170 and chassis 172 by determining the isolation between negative high voltage test input 114 and common test input 116 (which is the isolation between negative high voltage rail 178 and chassis 172) using the following equation from FMVSS305: Ri=Ro(1+V2/V1)[V1−V1′)/V1′] where Ri is the electrical isolation value in ohms, Ro is the resistivity of lower resistance 142 of negative side switched voltage divider network 120, V1 is Vb, is Vb′ and V2 is Va. If Vb is less than Va, then controller determines the isolation between high voltage system 170 and chassis 172 by determining the isolation between positive high voltage test input 114 and common test input 116 (which is the isolation between positive high voltage rail 176 and chassis 172) using the following equation from FMVSS305: Ri=Ro(1+V1/V2)[(V2−V2′)/V2′] where Ri is the electrical isolation value in ohms, Ro is the resistivity of lower resistance 130 of positive side switched voltage divider network 118, V1 is Vb, V2 is Va and V2″ is Va′. The controller then determines the electrical isolation value by dividing Ri by Vc (RiNc) the result of which must be equal to or greater than 500 to comply with FMVSS 305.

The control routine now proceeds to 214 where controller 154 sends the determined isolation Ri to a desired destination or destinations, such as display 166 and/or PC 168. In an aspect, controller 154 also sends Va, Va′, Vb, Vb′ and Vc to the desired destination or destinations. In an aspect, instead of controller 154 determining isolation Ri, controller 154 sends Va, Va′, Vb, Vb′ and Vc to a desired destination such as PC 168 that then determines isolation Ri as shown by phantom block 218 in FIG. 2.

Tester 100 provides a number of advantages. It isolates the user of tester 100 from the high voltage of high voltage system 170 since the high voltage side of tester 100 interfaces with high voltage system 170 (and chassis 172) illustratively by having test inputs 112, 114, 116 disposed in connector 180 that is plugged into a corresponding connector 182 of vehicle 174. The user of tester 100 thus does not need to have access to the high voltage test points on vehicle 174, such as the test points for positive high voltage rail 176 and negative high voltage rail 178. Tester 100, once its control routine such as the control routine of FIG. 2 is started, automatically makes the requisite voltage measurements and in an aspect determines the isolation between high voltage system 170 and chassis 172 of vehicle 174. These measurements can thus be done remotely and without the presence of a user in proximity to the tester. That is, tester 100 is plugged into vehicle 174 such as by a user of tester 100. The user can then leave the vicinity of vehicle 174 and initiate tester 100 to make the measurements such as via PC 168 communicating with controller 154 of tester 100 to initiate the control routine such as the control routine shown in FIG. 2.

Controller 154 in which the above described control routine is implemented is or includes any of a digital signal processor (DSP), microprocessor, microcontroller, or other programmable device which is programmed with software implementing the above described control. It should be understood that alternatively it is or includes other logic devices, such as a Field Programmable Gate Array (FPGA), a complex programmable logic device (CPLD), or application specific integrated circuit (ASIC). When it is stated that the controller 154 performs a function or is configured with control logic to perform a function, it should be understood that the controller 154 is configured to do so with appropriate logic (such as in software programmed in controller 154, logic devices, or a combination thereof).

The description of the invention is merely exemplary in nature and, thus, variations that do not depart from the gist of the invention are intended to be within the scope of the invention. Such variations are not to be regarded as a departure from the spirit and scope of the invention.

What is claimed is:

1. A high voltage isolation tester, comprising:
a high voltage side and a low voltage side that are coupled to each other by isolation amplifiers;
the high voltage side having a positive test input coupled by a positive side switched voltage divider network to an input of a first one of the isolation amplifiers, the positive side switched voltage divider network having first and second resistances that have different resistivities, a negative test input coupled by a negative side switched voltage divider network to an input of a second one of the isolation amplifiers, the negative side switched voltage divider network having third and fourth resistances that have different resistivities, and a common test input;
the positive test input and the negative test input also coupled to opposite sides of a voltage divider network of resistances with a junction of the resistances coupled to an input of a third one of the isolation amplifiers;
the low voltage side including an analog-to-digital converter to which outputs of the isolation amplifiers are coupled and a controller that controls switching of the switched voltage divider networks, reads from the analog-to-digital converter digitized data of voltage measurements of voltages across the high voltage test input and common test input, voltages across the negative high voltage test input and the common test input, and a voltage across the positive and negative high voltage test inputs; and
the controller configured with control logic to switch the positive side switched voltage divider network to couple the positive high voltage test input to the input of the first isolation amplifier through the first resistance and then through the second resistance and take voltage measurements of the voltage at the input of the first isolation amplifier when the positive high voltage test input is coupled to the input of the first isolation amplifier through the first resistance and also when the positive high voltage test input is coupled to the input of the first isolation amplifier through the second resistance, the controller also configured with control logic to switch the negative side switched voltage divider network to couple the negative high voltage test input to the input of the second isolation amplifier through the third resistance and then through the fourth resistance and take voltage measurements of the voltage at the input of the second isolation amplifier when the negative high voltage test input is coupled to the input of the second isolation amplifier through the third resistance and also when the negative high voltage test input is coupled to the input of the second isolation amplifier through the fourth resistance, the controller also configured with control logic to take a voltage measurement of a voltage at the input of the third isolation amplifier.

2. The tester of claim 1 wherein the controller is configured with control logic to determine isolation between the positive high voltage test input and the common test input and isolation between the negative high voltage test input and common test input based on the voltage measurements of the voltages at the inputs of the first and second isolation amplifiers.

3. The tester of claim 2 wherein the controller is configured with control logic to communicate each determined isolation to a desired destination.

4. The tester of claim 1 wherein the controller is configured with control logic to communicate the voltage measurements to a desired destination.
